(19) United States
(12) Patent Application Publication
(10) Pub. No.: US 2019/0332323 A1
(43) Pub. Date: Oct. 31, 2019

(54) MEMORY CONTROLLER, MEMORY SYSTEM, AND OPERATING METHOD THEREOF

(71) Applicant: SK hynix Inc., Gyeonggi-do (KR)

(72) Inventor: Hyeong Jae CHOI, Gyeonggi-do (KR)

(21) Appl. No.: 16/200,904

(22) Filed: Nov. 27, 2018

(30) Foreign Application Priority Data
Apr. 25, 2018 (KR) 10-2018-0047985

(51) Int. Cl. G06F 3/06; G11C 16/04; G11C 16/32; G11C 16/10

(52) U.S. Cl. CPC G06F 3/0659; G11C 16/0483; G11C 16/32; G06F 3/0673; G06F 3/0604; G06F 3/064; G11C 16/10

(57) ABSTRACT

A memory controller for controlling an operation of a memory device includes a time information buffer and a processing unit. The time information buffer stores a time information mapping table. The processing unit extracts time information from a write command received from a host, and updates the time information mapping table, based on the extracted time information.

### CROSS-REFERENCE TO RELATED APPLICATION

The present application claims priority under 35 U.S.C. § 119(a) to Korean patent application number 10-2018-0047985, filed on Apr. 25, 2018, which is incorporated herein by reference in its entirety.

### BACKGROUND

### Field of Invention

The present disclosure generally relates to an electronic device and, more particularly, to a memory controller and an operating method thereof.

### Description of Related Art

Semiconductor based memory devices (referred to hereinafter simply as memory devices) may be formed in a two-dimensional structure in which strings of memory cells are arranged horizontally on a semiconductor substrate. Memory devices may also be formed in a three-dimensional structure in which strings of memory cells are arranged vertically on a semiconductor substrate. A three-dimensional memory device was devised to overcome the limitations in the degree of integration of two-dimensional memory devices. Generally, a three-dimensional semiconductor memory device may include a plurality of memory cells vertically stacked on a semiconductor substrate. A memory controller may typically control the overall operations of a memory device. A system of a memory controller and a memory device is typically referred to as a memory system.

### SUMMARY

Various embodiments of the present invention provide a memory controller, a memory system employing the controller, and an operating method thereof. The memory controller can efficiently operate a memory device by adding time information to data to be stored in the memory device.

In accordance with an aspect of the present disclosure, there is provided a memory controller for controlling an operation of a memory device, the memory controller including: a time information buffer configured to store a time information mapping table; and a processing unit configured to extract time information from a write command received from a host, and to update the time information mapping table, based on the extracted time information.

The time information mapping table may be received from the memory device, and the time information may be information indicating a time at which the host generates the write command.

A program operation of the memory device may be controlled such that the updated time information is stored in the time information mapping table.

The time information mapping table may include: block identification information identifying at least one block in which data is stored; and at least one time information corresponding to the at least one block.

The time information may be the time information extracted from the write command corresponding to firstly stored data among data stored in a corresponding block.

The time information may be the time information extracted from the write command corresponding to lastly stored data among data stored in a corresponding block.

The time information mapping table may include: address information indicating a physical address at which data is stored; length information indicating a length of the data; and time information extracted from a write command corresponding to the data.

The time information buffer may further store final time information that is the time information extracted from a lastly received write command.

The processing unit may determine data on which a refresh operation is to be performed, based on the time information mapping table.

The processing unit may determine that a refresh operation is to be performed on data of which program lapse time exceeds a predetermined threshold time by comparing the final time information and the time information of the time information mapping table.

In accordance with another aspect of the present disclosure, there is provided a method for operating a memory controller, the method including: receiving a write command and write data corresponding thereto from a host; extracting time information from the write command; and updating a time information mapping table, based on the extracted time information, wherein the time information is information indicating a time at which the host generates the write command.

The method may further include controlling the memory device to program the updated time information mapping table.

The method may further include controlling the memory device to program the write data corresponding to the write command.

The updating of the time information mapping table may include: determining a physical address at which the write data is to be programmed; and updating the time information mapping table based on time information corresponding to the write data and the determined physical address.

In accordance with still another aspect of the present disclosure, there is provided a method for operating a memory controller, the method including: acquiring time information corresponding to a target data, based on a time information mapping table; calculating a program lapse time of the target data by comparing final time information that is time information extracted from a write command lastly received from a host and the time information of the target data; and performing a refresh operation of the target data, based on the program lapse time and a predetermined threshold time.

The performing of the refresh operation may include: comparing the program lapse time with the threshold time, performing, when the program lapse time is larger than the threshold time, a refresh operation on the target data; and updating the time information mapping table, based on the refresh operation.

The updating of the time information mapping table may include updating time information corresponding to the refreshed target data as the final time information.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those with ordinary skill in the art.

In the drawing figures, dimensions may be exaggerated for clarity of illustration. Moreover, it will be understood that when an element is referred to as being “between” two elements, it can be the only element between the two elements, or one or more intervening elements may also be present. Like reference numerals refer to like elements throughout.

FIG. 1 is a block diagram illustrating an example of a memory system operatively coupled to a host.

FIG. 2 is a block diagram illustrating an exemplary configuration of a memory device shown in FIG. 1.

FIG. 3 is a diagram illustrating a three-dimensional embodiment of a memory cell array shown in FIG. 2.

FIG. 4 is an exemplary circuit diagram illustrating any one memory block among a plurality of identical memory blocks employed in the memory cell array shown in FIG. 3.

FIG. 5 is another exemplary circuit diagram illustrating any one memory block among a plurality of identical memory blocks employed in the memory cell array shown in FIG. 3.

FIG. 6 is yet another exemplary circuit diagram illustrating any one memory block among a plurality of identical memory blocks employed in the memory cell array shown in FIG. 2.

FIG. 7 is a block diagram illustrating a more detailed configuration of the memory system shown in FIG. 1.

FIG. 8A is a diagram illustrating schematically a write operation of the memory system.

FIG. 8B is a diagram illustrating schematically a read operation of the memory system.

FIG. 9A is a diagram illustrating an exemplary structure of a write command that is used in an operating method of a memory controller in accordance with an embodiment of the present disclosure.

FIG. 9B is a diagram illustrating an exemplary structure of write data used in an operating method of the memory controller in accordance with an embodiment of the present disclosure.

FIG. 10A is a diagram illustrating another exemplary structure of a write command used in an operating method of the memory controller in accordance with an embodiment of the present disclosure.

FIG. 10B is a diagram illustrating another exemplary structure of write data used in an operating method of the memory controller in accordance with the embodiment of the present disclosure.

FIG. 11 is a diagram illustrating still another exemplary structure of a write command and write data used in an operating method of the memory controller in accordance with the embodiment of the present disclosure.

FIG. 12A is a diagram illustrating an exemplary structure of a time information mapping table generated in accordance with an embodiment of the present disclosure.

FIG. 12B is a diagram illustrating another exemplary structure of a time information mapping table generated in accordance with an embodiment of the present disclosure.

FIG. 13 is a flowchart illustrating an operating method of the memory controller in accordance with another embodiment of the present disclosure.

FIG. 14 is a diagram illustrating a time information mapping table stored in a memory cell array of a memory device in accordance with an embodiment of the present disclosure.

FIG. 15A is a block diagram illustrating a process of updating time information mapping table by receiving a write command from a host in accordance with an embodiment of the present disclosure.

FIG. 15B is a block diagram illustrating a process of storing write data and an updated time information mapping table in the memory device in accordance with an embodiment of the present disclosure.

FIG. 16 is a diagram illustrating a time information buffer for storing time information mapping table and final time information in accordance with an embodiment of the present disclosure.

FIG. 17 is a flowchart illustrating an operating method of the memory controller in accordance with another embodiment of the present disclosure.

FIG. 18 is a diagram illustrating another embodiment of a memory system including the memory controller shown in FIG. 7.

FIG. 19 is a diagram illustrating another embodiment of a memory system including the memory controller shown in FIG. 7.

FIG. 20 is a diagram illustrating another embodiment of a memory system including the memory controller shown in FIG. 7.

FIG. 21 is a diagram illustrating another embodiment of a memory system including the memory controller shown in FIG. 7.

### DETAILED DESCRIPTION

In the following detailed description, only certain exemplary embodiments of the present disclosure have been shown and described, simply by way of illustration. As those with ordinary skill in the art of the present invention would realize, the described embodiments may be modified in various different ways without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless specifically stated otherwise.

Hereinafter, exemplary embodiments of the present disclosure will be described in detail with reference to the accompanying drawings. The same reference numerals are used to designate the same elements in various drawings. In the following descriptions, only features (and or functions) necessary for understanding the operations in accordance with the exemplary embodiments may be described, and descriptions of other features (and or functions) may be omitted so as to not obscure the disclosure of the various embodiments of the present invention.

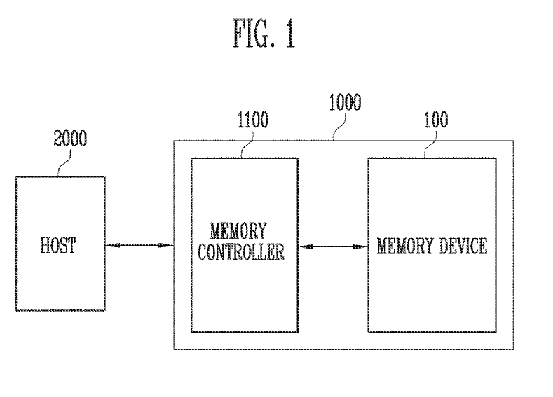

FIG. 1 is a block diagram illustrating an example of a memory system operatively coupled to a host.

Referring to FIG. 1, the memory system 1000 includes a memory device 100 and a memory controller 1100 operatively coupled to each other.

The memory device 100 may operate under the controlof the memory controller 1100. More specifically, the memory device 100 may write data in a memory cell array in response to a write request from the memory controller 1100. When a write command, an address, and data are received as a write request from the memory controller 1100, the memory device 100 writes data in one or more memory cells indicated by the received address.

The memory device 100 may perform a read operation in response to a read request from the memory controller 1100. For example, when a read command and an address are received as a read request from the memory controller 1100, the memory device 100 reads data of one or more memory cells indicated by the received address, and outputs the read data to the memory controller 1100.

The memory device 100 may be a NAND flash memory, a vertical NAND flash memory, a NOR flash memory, a Resistive Random-Access Memory (RRAM), a Phase-Change Random-Access Memory (PRAM), a Magnetoresistive Random-Access Memory (MRAM), a Ferroelectric Random-Access Memory (FRAM), a Spin Transfer Torque Random-Access Memory (STT-RAM), or the like. The memory device 100 may be implemented in a three-dimensional array structure. Moreover, it is noted that the present invention may be applied not only to a flash memory device in which a charge storage layer is configured with a Floating Gate (FG) but may also applied to a Charge Trap Flash (CTF) in which a charge storage layer is configured with an insulating layer.

The memory controller 1100 operatively couples the memory device 100 to a host 2000. The memory controller 1100 is configured to interface the host 2000 and the memory device 100. For example, the memory controller 1100 may transmit a write request and/or a read request to the memory device 100 under the control of the host 2000. The memory controller 1100 may also transmit data to and from the memory device 100 and the host 2000.

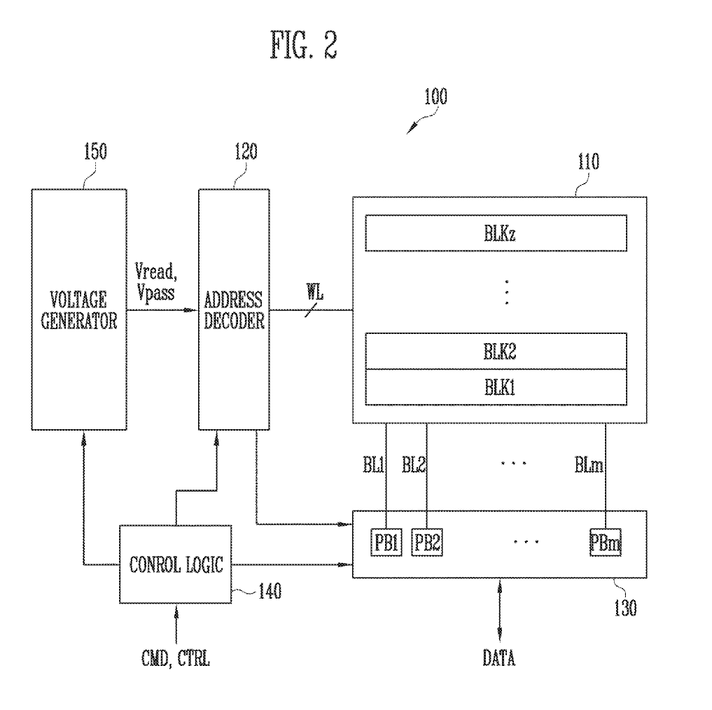

FIG. 2 is a block diagram illustrating an exemplary configuration of the memory device of FIG. 1.

Referring to FIG. 2, the memory device 100 includes a memory cell array 110, an address decoder 120, a read/write circuit 130, a control logic 140, and a voltage generator 150.

The memory cell array 110 includes a plurality of memory blocks BLK1 to BLKz. The plurality of memory blocks BLK1 to BLKz are coupled to the address decoder 120 through word lines WL. The plurality of memory blocks BLK1 to BLKz are coupled to the read/write circuit 130 through bit lines BL1 to BLm. Each of the plurality of memory blocks BLK1 to BLKz includes a plurality of memory cells. In an embodiment, the plurality of memory cells are nonvolatile memory cells, and may be configured as nonvolatile memory cells having a vertical channel structure. The memory cell array 110 may be configured as a memory cell array having a two-dimensional structure. In some embodiments, the memory cell array 110 may be configured as a memory cell array having a three-dimensional structure. Meanwhile, each of the plurality of memory cells included in the memory cell array 110 may store data of at least one bit. In an embodiment, each of the plurality of memory cells included in the memory cell array 110 may be a single-level cell (SLC) that stores data of one bit. In another embodiment, each of the plurality of memory cells included in the memory cell array 110 may be a multi-level cell (MLC) that stores data of two bits. In still another embodiment, each of the plurality of memory cells included in the memory cell array 110 may be a triple-level cell that stores data of three bits. In still another embodiment, each of the plurality of memory cells included in the memory cell array 110 may be a quad-level cell that stores data of four bits. In some embodiments, the memory cell array 110 may include a plurality of memory cells that each stores data of five or more bits.

The address decoder 120, the read/write circuit 130, the control logic 140, and the voltage generator 150 operate as a peripheral circuit that drives the memory cell array 110. The address decoder 120 is coupled to the memory cell array 110 through the word lines WL. The address decoder 120 is configured to operate under the control of the control logic 140. The address decoder 120 receives an address through an input/output buffer (not shown) provided in the memory device 100.

The address decoder 120 is configured to decode a block address in the received address. The address decoder 120 selects at least one memory block according to the decoded block address. In a read voltage application operation during a read operation, the address decoder 120 applies a read voltage Vread generated by the voltage generator 150 to a selected word line among the selected memory blocks, and applies a pass voltage Vpass to the other unselected word lines. In a program verify operation, the address decoder 120 applies a verify voltage generated by the voltage generator 150 to the selected word line among the selected memory blocks, and applies the pass voltage Vpass to the other unselected word lines.

The address decoder 120 is configured to decode a column address in the received address. The address decoder 120 transmits the decoded column address to the read/write circuit 130.

Read and program operations of the memory device 100 are performed in units of pages. An address received in a request of the read operation and the program operation includes a block address, a row address, and a column address. The address decoder 120 selects one memory block and one word line according to the block address and the row address. The column address is decoded by the address decoder 120 to be provided to the read/write circuit 130.

The address decoder 120 may include a block decoder, a row decoder, a column decoder, an address buffer, and the like.

The read/write circuit 130 includes a plurality of page buffers PB1 to PBm. The read/write circuit 130 may operate as a “read circuit” in a read operation of the memory cell array 110, and operate as a “write circuit” in a write operation of the memory cell array 110. The plurality of page buffers PB1 to PBm are coupled to the memory cell array 110 through the bit lines BL1 to BLm. In order to sense threshold voltages of memory cells in the read operation and the program verify operation, the plurality of page buffers PB1 to PBm sense a change in amount of current flowing depending on a program state of a corresponding memory cell while continuously supplying sensing current to bit lines coupled to the memory cells, and latch the sensed change as sensing data. The read/write circuit 130 operates in response to page buffer control signals output from the control logic 140.

In the read operation, the read/write circuit 130 temporarily stores read data by sensing data of a memory cell and then outputs data DATA to the input/output buffer (not shown) of the memory device 100. In an exemplary embodiment, the read/write circuit 130 may include a column selection circuit, and the like, in addition to the page buffers (or page registers).

The control logic 140 is coupled to the address decoder 120, the read/write circuit 130, and the voltage generator 150. The control logic 140 receives a command CMD and a control signal CTRL through the input/output buffer (not shown) of the memory device 100. The control logic 140 is configured to control overall operations of the memory device 100 in response to the control signal CTRL. Also, the control logic 140 outputs a control signal for controlling sensing node precharge potential levels of the plurality of page buffers PB1 to PBm. The control logic 140 may control the read/write circuit 130 to perform the read operation of the memory cell array 110.

In the read operation, the voltage generator 150 generates the read voltage Vread and the pass voltage Vpass in response to a control signal output from the control logic 140. In order to generate a plurality of voltages having various voltage levels, the voltage generator 150 may include a plurality of pumping capacitors for receiving an internal power voltage, and generate a plurality of voltages by selectively activating the plurality of pumping capacitors under the control of the control logic 140.

The address decoder 120, the read/write circuit 130, and the voltage generator 150 may serve as a “peripheral circuit” that performs a read operation, a write operation, and an erase operation on the memory cell array 110. The peripheral circuit performs the read operation, the write operation, and the erase operation on the memory cell array 110 under the control of the control logic 140.

FIG. 3 is a diagram illustrating an embodiment of the memory cell array of FIG. 2.

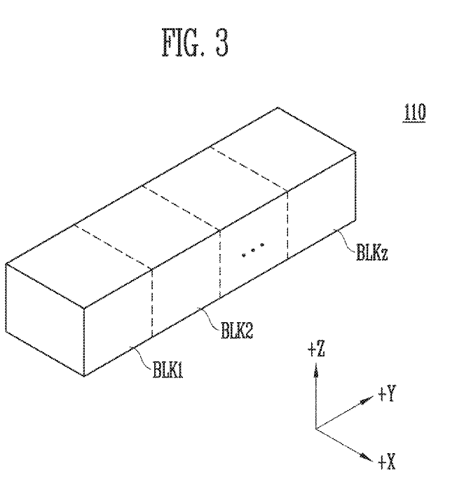

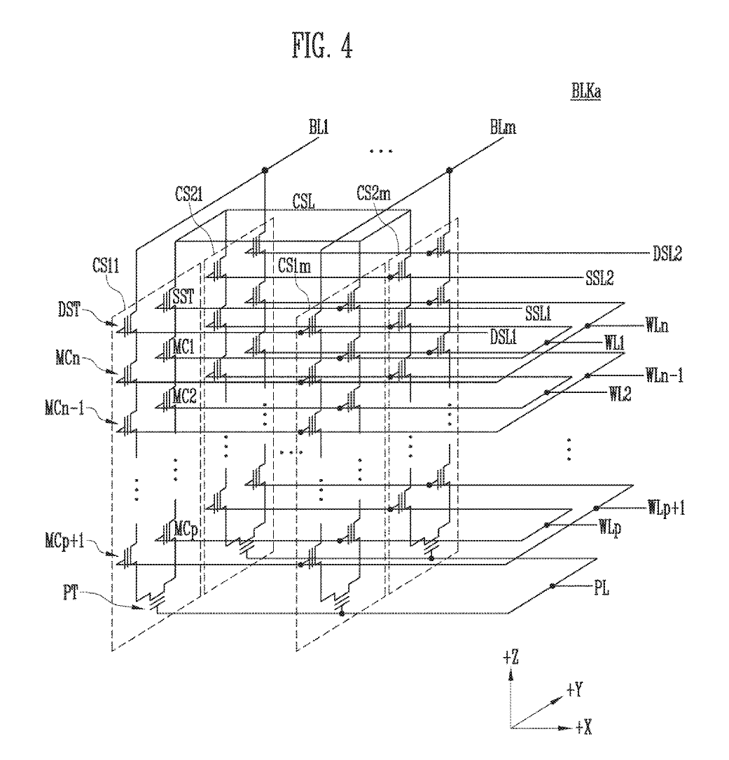

Referring to FIG. 3, the memory cell array 110 includes a plurality of memory blocks BLK1 to BLKz. Each memory block has a three-dimensional structure. Each memory block includes a plurality of memory cells stacked above a substrate. The plurality of memory cells are arranged along +X, +Y, and +Z directions. The structure of each memory block will be described in more detail with reference to FIGS. 4 and 5.

FIG. 4 is a circuit diagram illustrating any one memory block BLKa among the identical memory blocks BLK1 to BLKz of FIG. 3.

Referring to FIG. 4, the memory block BLKa includes a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings are arranged in a row direction (i.e., a +X direction). In FIG. 4, it is illustrated that two cell strings are arranged in a column direction (i.e., a +Y direction). However, this is for convenience of description, and it will be understood that three cell strings may be arranged in the column direction.

Each of the plurality of cell strings CS11 to CS1m and CS21 to CS2m includes at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and memory cells MC1 to MCp.

In an embodiment, the source select transistors of cell strings arranged on the same row are coupled to a source select line extending in the row direction, and the source select transistors of cell strings arranged on different rows are coupled to different source select lines. In FIG. 4, the source select transistors of the cell strings CS11 to CS1m on a first row are coupled to a first source select line SSL1. The source select transistors of the cell strings CS21 to CS2m on a second row are coupled to a second source select line SSL2.

In another embodiment, the source select transistors of the cell strings CS11 to CS1m and CS21 to CS2m may be commonly coupled to one source select line.

The first to nth memory cells MC1 to MCn of each cell string are coupled between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp are sequentially arranged in the opposite direction of a +Z direction, and are coupled in series between the source select transistor SST and the pipe transistor PT. The (p+1)th to nth memory cells MCp+1 to MCn are sequentially arranged in the +Z direction, and are coupled in series between the pipe transistor PT and the drain select transistor DST. The first to pth memory cells MC1 to MCp and the (p+1)th to nth memory cells MCp+1 to MCn are coupled through the pipe transistor PT. Gate electrodes of the first to nth memory cells MC1 to MCn of each cell string are coupled to first to nth word lines WL1 to WLn, respectively.

A gate of the pipe transistor PT of each cell string is coupled to a pipe line PL.

The drain select transistor DST of each cell string is coupled between a corresponding bit line and the memory cells MCp+1 to MCn. Cell strings arranged in the row direction are coupled to a drain select line extending in the row direction. The drain select transistors of the cell strings CS11 to CS1m on the first row are coupled to a first drain select line DSL1. The drain select transistors of the cell strings CS21 to CS2m on the second row are coupled to a second drain select line DSL2.

Cell strings arranged in the column direction are coupled to a bit line extending in the column direction. In FIG. 4, the cell strings CS11 and CS21 on a first column are coupled to a first bit line BL1. The cell strings CS1m and CS2m on an mth column are coupled to an mth bit line BLm.

Memory cells coupled to the same word line in the cell strings arranged in the row direction constitute one page. For example, memory cells coupled to the first word line WL1 in the cell strings CS11 to CS1m on the first row constitute one page. Memory cells coupled to the first word line WL1 in the cell strings CS21 to CS2m on the second row constitute another page. When any one of the drain select lines DSL1 and DSL2 is selected, cell strings arranged in one row direction may be selected. When any one of the word lines WL1 to WLn is selected, one page may be selected in the selected cell strings.

In another embodiment, even bit lines and odd bit lines may be provided instead of the first to mth bit lines BL1 to BLm. In addition, even-numbered cell strings among the cell strings CS11 to CS1m or CS21 to CS2m arranged in the row direction may be coupled to the even bit lines, respectively, and odd-numbered cell strings among the cell strings CS11 to CS1m or CS21 to CS2m arranged in the row direction may be coupled to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. When the number of dummy memory cells increases, the reliability of an operation of the memory block BLKa is improved. On the other hand, the size of the memory block BLKa increases. When the number of dummy memory cells decreases, the size of the memory block BLKa decreases. On the other hand, the reliability of an operation of the memory block BLKa may be deteriorated.

In order to efficiently control the at least one dummy memory cell, the dummy memory cells may have a required threshold voltage. Before or after an erase operation of the memory block BLKa, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

FIG. 5 is a circuit diagram illustrating another embodiment BLKb of the one memory block among the memory blocks BLK1 to BLKz of FIG. 3.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ extends along the +Z direction. Each of the plurality of cell strings CS11′ to CS1m′ and CS21′ to CS2m′ includes at least one source select transistor SST, first to nth memory cells MC1 to MCn, and at least one drain select transistor DST, which are stacked on a substrate (not shown) under the memory block BLKb.

The source select transistor SST of each cell string is coupled between a common source line CSL and the memory cells MC1 to MCn. The source select transistors of cell strings arranged on the same row are coupled to the same source select line. The source select transistors of the cell strings CS11′ to CS1m′ arranged on a first row are coupled to a first source select line SSL1. Source select transistors of the cell strings CS21′ to CS2m′ arranged on a second row are coupled to a second source select line SSL2. In another embodiment, the source select transistors of the cell strings CS11′ to CS1′ and CS21′ to CS2m′ may be commonly coupled to one source select line.

The first to nth memory cells MC1 to MCn of each cell string are coupled in series between the source select transistor SST and the drain select transistor DST. Gate electrodes of the first to nth memory cells MC1 to MCn are coupled to first to nth word lines WL1 to WLn, respectively.

The drain select transistor DST of each cell string is coupled between a corresponding bit line and the memory cells MC1 to MCn. The drain select transistors of cell strings arranged in the row direction are coupled to a drain select line extending in the row direction. The drain select transistors of the cell strings CS11′ to CS1m′ on the first row are coupled to a first drain select line DSL1. The drain select transistors of the cell strings CS21′ to CS2m′ on the second row are coupled to a second drain select line DSL2.

Consequently, the memory block BLKb of FIG. 5 has a circuit similar to that of the memory block BLKa of FIG. 4, except that the pipe transistor PT is excluded from each cell string.

In another embodiment, even bit lines and odd bit lines may be provided instead of the first to mth bit lines BL1 to BLm. In addition, even-numbered cell strings among the cell strings CS11′ to CS1m′ or CS21′ to CS2m′ arranged in the row direction may be coupled to the even bit lines, respectively, and odd-numbered cell strings among the cell strings CS11′ to CS1m′ or CS21′ to CS2m′ arranged in the row direction may be coupled to the odd bit lines, respectively.

In an embodiment, at least one of the first to nth memory cells MC1 to MCn may be used as a dummy memory cell. For example, the at least one dummy memory cell may be provided to decrease an electric field between the source select transistor SST and the memory cells MC1 to MCp. Alternatively, the at least one dummy memory cell may be provided to decrease an electric field between the drain select transistor DST and the memory cells MCp+1 to MCn. When the number of dummy memory cells increases, the reliability of an operation of the memory block BLKb is improved. On the other hand, the size of the memory block BLKb increases. When the number of dummy memory cells decreases, the size of the memory block BLKb decreases. On the other hand, the reliability of an operation of the memory block BLKb may be deteriorated.

In order to efficiently control the at least one dummy memory cell, the dummy memory cells may have a required threshold voltage. Before or after an erase operation of the memory block BLKb, a program operation may be performed on all or some of the dummy memory cells. When an erase operation is performed after the program operation is performed, the threshold voltage of the dummy memory cells control a voltage applied to the dummy word lines coupled to the respective dummy memory cells, so that the dummy memory cells can have the required threshold voltage.

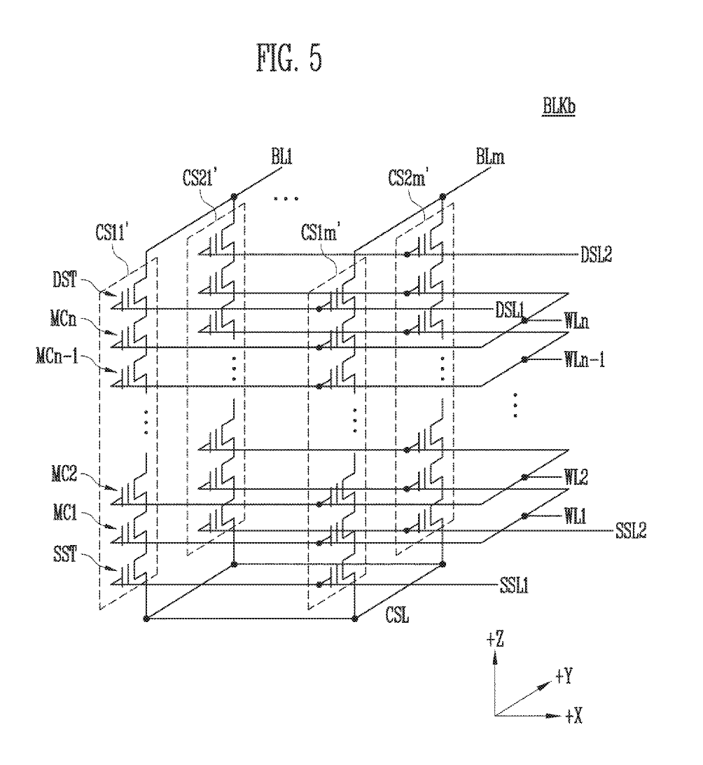

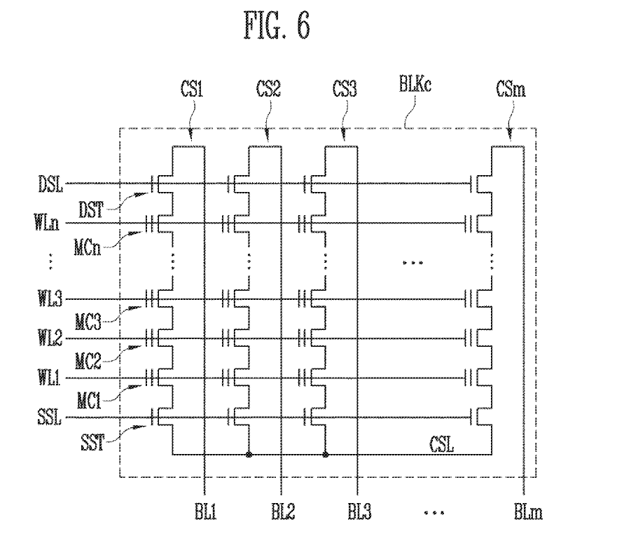

FIG. 6 is a circuit diagram illustrating an embodiment of any one memory block BLKc among the plurality of memory blocks BLK1 to BLKz included in the memory cell array of FIG. 2.

Referring to FIG. 6, the memory block BLKc includes a plurality of strings CS1 to CSm. The plurality of strings CS1 to CSm may be coupled to a plurality of bit lines BL1 to BLm, respectively. Each of the plurality of strings CS1 to CSm includes at least one source select transistor SST, first to nth memory cells MC1 to MCn, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and the memory cells MC1 to MCn.

The first to nth memory cells MC1 to MCn of each cell string is coupled between the source select transistor SST and the drain select transistor DST.

The drain select transistor DST of each cell string is coupled between a corresponding bit line and the memory cells MC1 to MCn.

Memory cells coupled to the same d line constitute one page. As a drain select line DSL is selected, the cell strings CS1 to CSm may be selected. As any one of word lines WL1 to WLn is selected, one page among selected cell strings may be selected.

In another embodiment, even bit lines and odd bit lines may be provided instead of the first to mth bit lines BL1 to BLm. Even-numbered cell strings among the cell strings CS1 to CSm arranged may be coupled to the even bit lines, respectively, and odd-numbered cell strings among the cell strings CS1 to CSm may be coupled to the odd bit lines, respectively.

As shown in FIGS. 3 to 5, the memory cell array 110 of the memory device 100 may be configured as a memory cell array having a three-dimensional structure. In addition, as shown in FIG. 6, the memory cell array 110 of the memory device 100 may be configured as a memory cell array having a two-dimensional structure.

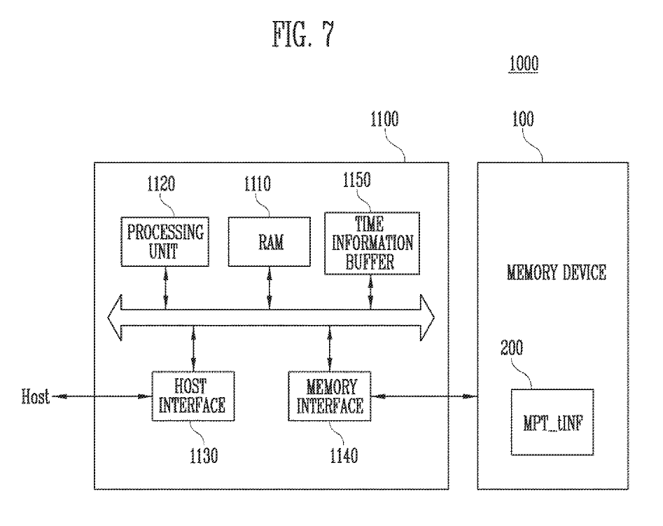

FIG. 7 is a block diagram illustrating a more detailed configuration of the memory system 1000 of FIG. 1.

Referring to FIG. 7, the memory system 1000 includes the memory device 100 and the memory controller 1100. The memory controller 1100 is operatively coupled to a host Host and the memory device 100. The memory controller 1100 is configured to access the memory device 100 in response to a request from the host Host. For example, the memory controller 1100 is configured to control read, write, erase, and background operations of the memory device 100. The memory controller 1100 is configured to provide an interface between the memory device 100 and the host Host.

The memory device 100 may be the memory device 100 described with reference to FIG. 2. The memory device 100 may store a time information mapping table MTP_tINF 200. The time information mapping table MTP_tINF 200 may be generated or updated by the memory controller 1100, to be stored in the memory device 100.

The memory controller 1100 includes a Random-Access Memory (RAM) 1110, a processing unit 1120, a host interface 1130, a memory interface 1140, and a time information buffer 1150. The RAM 1110 is used as at least one of a working memory of the processing unit 1120, a cache memory between the memory device 100 and the host Host, and a buffer memory between the memory device 100 and the host Host. The processing unit 1120 controls the overall operations of the memory controller 1100. In addition, the memory controller 1100 may temporarily store program data provided from the host Host in a write operation.

The host interface 1130 includes a protocol suitable for exchanging data between the host Host and the memory controller 1100. In an exemplary embodiment, the memory controller 1100 is configured to communicate with the host Host through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer Small Interface (SCSI) protocol, an Enhanced Small Disk Interface (ESDI) protocol, an Integrated Drive Electronics (IDE) protocol, and a private protocol.

The memory interface 1140 interfaces the controller 1100 with the memory device 100. For example, the memory interface 1140 may include a NAND interface or a NOR interface.

The time information buffer 1150 may store the time information mapping table MTP_tINF 200. The time information buffer 1150 may be configured as an SRAM or DRAM. In some embodiments, the time information buffer 1150 may be configured as a portion of the RAM 1110. Meanwhile, the time information buffer 1150 may store the time information mapping table 200 only while the memory system 1000 is being turned on.

The processing unit 1120 may extract time information from a write command or write data, which is received from the host Host. Meanwhile, the processing unit 1120 may generate or update the time information mapping table MTP_tINF, based on the extracted time information. The generated or updated time information mapping table MTP_tINF may be stored in the time information buffer 1150. Meanwhile, the memory controller 1100 may control a program operation of the memory device 100, to store the generated or updated time information mapping table MTP_tINF.

In the memory controller 1100 in accordance with an embodiment of the present disclosure, the time information mapping table MTP_tINF is written and updated by extracting time information from a write command or write data, which is received from the host. The time information may be information indicating a time at which the host generates the write command. The memory controller 1100 refers to the time information mapping table MTP_tINF, to monitor a program time of data stored in the memory device 100. Accordingly, data can be managed according to their program time at the level of the memory controller 1100.

The memory controller 1100 and the memory device 100 may be integrated into one semiconductor device. In an exemplary embodiment, the memory controller 1100 and the memory device 100 may be integrated into one semiconductor device, to constitute a memory card. For example, the memory controller 1100 and the memory device 100 may be integrated into one semiconductor device, to constitute a memory card such as a PC card (Personal Computer Memory Card International Association (PCMCIA)), a Compact Flash (CF) card, a Smart Media Card (SM or SMC), a memory stick, a Multi-Media Card (MMC, RS-MMC or MMCmicro), an SD Card (SD, miniSD, microSD or SDHC), or a Universal Flash Storage (UFS).

The memory controller 1100 and the memory device 100 may be integrated into one semiconductor device to constitute a semiconductor drive also referred to as a Solid State Drive (SSD). The SSD includes a storage device configured to store data in a semiconductor memory. When the memory system 1000 is used as the SSD, the operating speed of the host Host coupled to the memory system 1000 can be remarkably improved.

In another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multi-Media Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the memory device 100 or the memory system 1000 may be packaged in various forms. For example, the memory device 100 or the memory system 1000 may be packaged in a manner such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), Plastic Metric Quad Flat Pack (PMQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi-Chip Package (MCP), Wafer-level Fabricated Package (WFP), or Wafer-level processed Stack Package (WSP).

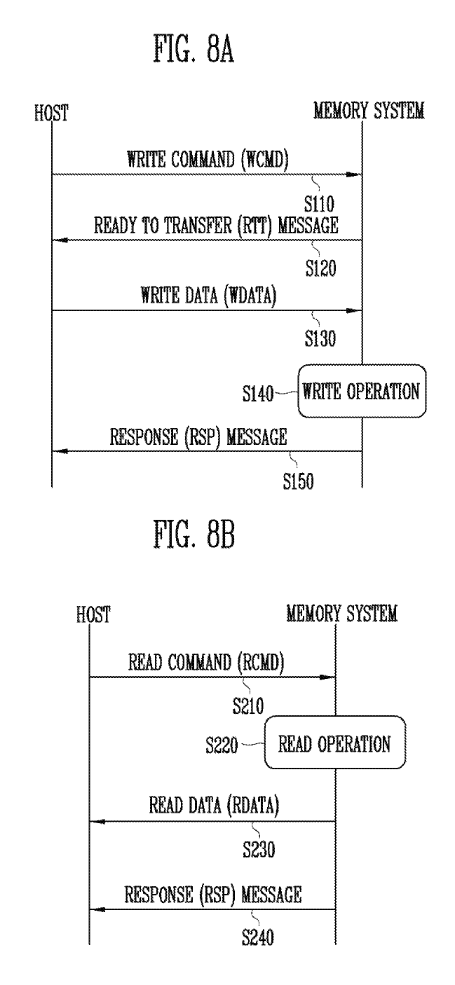

FIG. 8A is a diagram illustrating a write operation of the memory system 1000.

Referring to FIG. 8A, the host 2000 transfers a write command WCMD to the memory system 1000 in step S110. When the memory system 1000 is completely ready to receive the write data (WDATA), the memory system 1000 transfers a ready to transfer (RTT) message to the host 2000 in step S120. The host 2000 then transfers write data WDATA to the memory system 1000 in response to the RTT message in step S130. The memory system 1000 performs a write operation on the received write data WDATA in step S140. More specifically, the memory controller 1100 may control the memory device 100 to program the received write data WDATA.

When the write operation is completed, the memory system 1000 transfers a response (RSP) message to the host 2000 in step S150. FIG. 8A illustrates that the RSP message is transferred after the write operation is completed. However, in some embodiments, the RSP message may be transferred to the host 2000 before the write operation is completed.

By the procedure shown in FIG. 8A, the write operation is performed in response to a request from the host 2000.

FIG. 8B is a diagram illustrating a read operation of the memory system 1000.

Referring to FIG. 8B, the host 2000 transfers a read command RCMD to the memory system 1000 in step S210. The memory system 1000 performs a read operation in response to the read command RCMD in step S220. More specifically, the read operation on data stored in the memory device 100 may be performed by the memory controller 1100.

Subsequently, the memory system 1000 transfers read data RDATA to the host 2000 in step S230. After the read data RDATA is completely transferred, the memory system 1000 may transfer a response (RSP) message to the host 2000 in step S240.

By the procedure shown in FIG. 8B, the read operation is performed in response to a read request received from the host 2000.

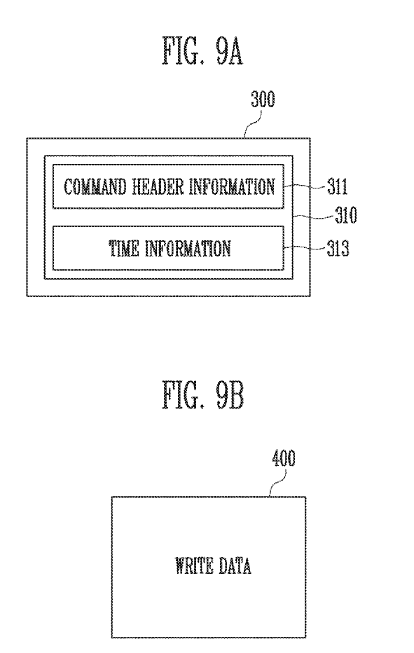

FIG. 9A is a diagram illustrating an exemplary structure of a write command WCMD used in an operating method of the memory controller 1100 in accordance with an embodiment of the present disclosure. FIG. 9B is a diagram illustrating an exemplary structure of write data WDATA used in an operating method of the memory controller 1100 in accordance with an embodiment of the present disclosure. Hereinafter, these will be described with reference to FIGS. 9A and 9B together.

Referring to FIG. 9A, the write command WCMD 300 transferred in the step S110 of FIG. 8A includes a header 310. The header 310 may include command header information 311 and time information 313. The host 2000 may generate the write command WCMD 300 by inserting the time information 313 corresponding to a time, at which the write command WCMD 300 is generated, into the header 310. Referring to FIG. 9B, the write data WDATA 400 is data corresponding to the write command WCMD of FIG. 9A. Although not shown in FIG. 9B, the write data WDATA 400 may include user data and Cyclic Redundancy Check (CRC) data. The CRC data may be data for checking whether an error has occurred in the user data.

As shown in FIGS. 9A and 9B, the host 2000 may insert the time information 313 into the header 310 of the write command WCMD 300. The time information 313 may be information indicating a time at which the write command WCMD 300 is generated. Therefore, the memory controller 1100 may detect the time at which the write command WCMD 300 is generated by analyzing the header 310 of the received write command WCMD 300. In addition, the memory controller 1100 may generate or update the time information mapping table MTP_tINF, based on the time information 313 of the write command WCMD 300. Accordingly, the memory controller 1100 can more flexibly perform various operations, based on time information corresponding to the write data WDATA 400.

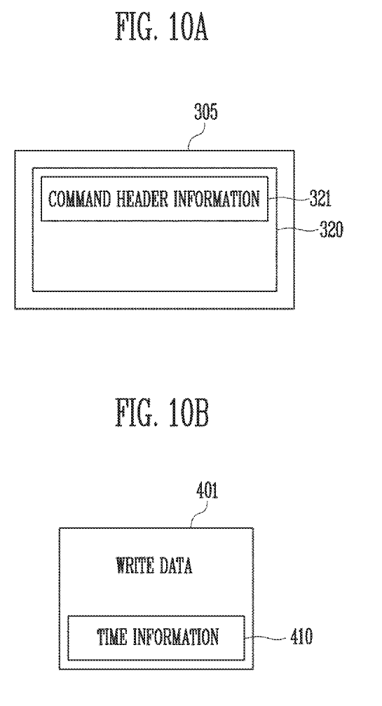

FIG. 10A is a diagram illustrating another exemplary structure of a write command WCMD used in an operating method of the memory controller 1100 in accordance with an embodiment of the present disclosure. FIG. 10B is a diagram illustrating another exemplary structure of write data WDATA used in an operating method of the memory controller 1100 in accordance with an embodiment of the present disclosure. Hereinafter, these will be described with reference to FIGS. 10A and 10B together.

Referring to FIG. 10A, the write command WCMD 305 transferred in the step S110 of FIG. 8A includes a header 320. The header 320 may include command header information 321. Referring to FIG. 10B, the write data WDATA 401 is data corresponding to the write command WCMD of FIG. 10A. Although not shown in detail in FIG. 10B, the write data WDATA 401 may include user data and CRC data. The CRC data may be data for checking whether an error has occurred in the user data.

The write data WDATA 401 may also include time information 410. The host 2000 may insert the time information 410 corresponding to a time, at which the write command WCMD 305 is generated, into the write data 401.

As shown in FIGS. 10A and 10B, the host 2000 may insert the time information 410 into the write data WDATA 401. The time information 410 may be information indicating the time at which the write command WCMD 305 is generated. Therefore, the memory controller 1100 may detect the time at which the write command WCMD 305 is generated by analyzing the received write data WDATA 401. In addition, the memory controller 1100 may generate or update the time information mapping table MTP_tINF, based on the time information 410 of the write data WDATA 401. Accordingly, the memory controller 1100 can more flexibly perform various operations, based on time information corresponding to the write data.

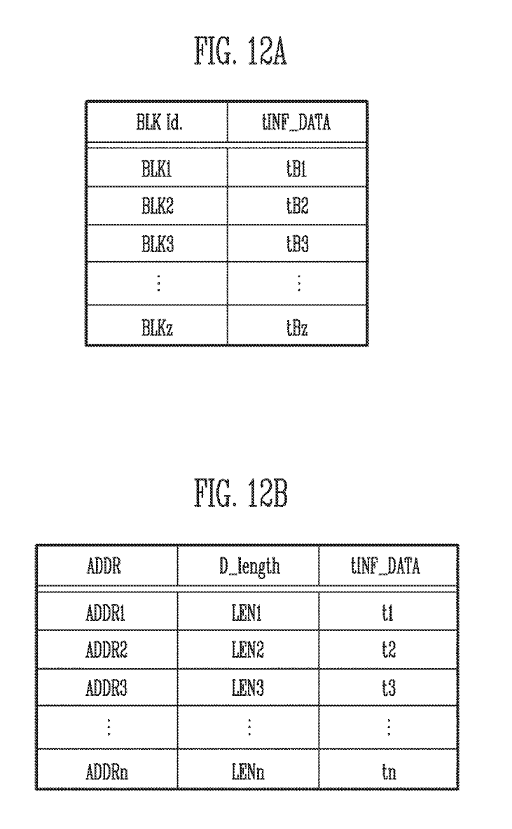

Configurations of the time information mapping table will be described later with reference to FIGS. 12A and 12B.

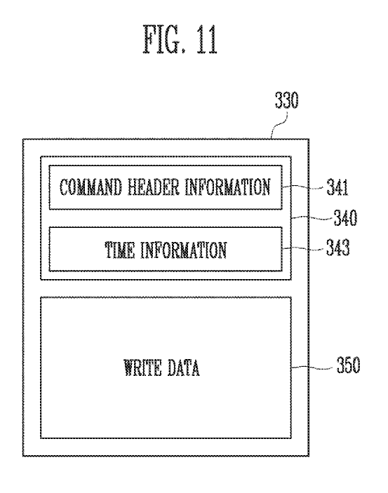

FIG. 11 is a diagram illustrating still another exemplary structure of a write command WCMD and write data WDATA, which are used in an operating method of the memory controller 1100 in accordance with an embodiment of the present disclosure.

Referring to FIG. 11, the write command WCMD 330 may include a header 340 and write data 350. In the embodiment of FIG. 11, the write command and the write data are not separated from each other, but may be generated as one data. The header 340 may include command header information 341 and time information 343. The host 2000 may generate the write command WCMD 330 by inserting the time information 343 corresponding to a time, at which the write command WCMD 330 is generated, into the header 340. Meanwhile, the write data WDATA 350 may include user data and CRC data. The CRC data may be data for checking whether an error has occurred in the user data. In accordance with the embodiment shown in FIG. 11, it can be seen that the write data 330 is not transferred separately from the write command 330 but transferred together with the write command 330. The memory controller 1100 may extract the time information 343 by analyzing the header 340 of the received write command 330. The memory controller 110 may generate and update the time information mapping table MTP_tINF, based on the extracted time information 343. Accordingly, the memory controller 1100 can more flexibly perform various operations, based on time information corresponding to the write data WDATA 350.

FIG. 12A is a diagram illustrating an exemplary structure of a time information mapping table MTP_tINF generated in accordance with an embodiment of the present disclosure.

Referring to FIG. 12A, the time information mapping table MTP_tINF includes a block ID BLK Id. field and a time information data tINF_DATA field. Each entry of the time information mapping table MTP_tINF represents time information of a corresponding memory block. In FIG. 12A, time information data tB1 to tBz corresponding to first to zth memory blocks BLK1 to BLKz are stored in the time information mapping table MTP_tINF.

In FIG. 12A, time information data tINF_DATA corresponding to each memory block of the memory device 100 is stored. For example, referring to a first entry, a time tB1 corresponding to the first memory block BLK1 is stored. This means that the time at which a write command WCMD corresponding to data stored in the first memory block BLK1 is generated is a time indicated by the time tB1.

When data corresponding to one write command is stored in one block, the time information data tINF_DATA may indicate a time at which the one write command is generated.

However, data respectively corresponding to two or more write commands may be stored in one block. A time at which the write command corresponding to any one of the data stored in the one block is generated may be stored as the time information data tINF_DATA.

In an embodiment, a time at which a write command corresponding to firstly stored data among a plurality of data stored in a memory block corresponding to the block ID BLK Id. is generated may be stored as the time information data tINF_DATA. For example, when up assuming that a plurality of data programmed respectively by a plurality of write commands are stored in the second memory block BLK2, a time at which a write command corresponding to firstly programmed data among the plurality of data is generated among the plurality of write commands may be stored as the time tB2.

In another embodiment, a time at which a write command corresponding to lastly stored data among a plurality of data stored in a memory block corresponding to the block ID BLK Id. is generated may be stored as the time information data tINF_DATA. For example, when assuming that a plurality of data programmed respectively by a plurality of write commands are stored in the second memory block BLK2, a time at which a write command corresponding to lastly programmed data among the plurality of data is generated among the plurality of write commands may be stored as the time tB2. According to the time information mapping table in the example of FIG. 12A, time information is managed for each memory block.

FIG. 12B is a diagram illustrating another exemplary structure of a time information mapping table generated in accordance with an embodiment of the present disclosure.

Referring to FIG. 12B, the time information mapping table MTP_tINF includes an address ADDR field, a data length D_length field, and a time information data tINF_DATA field. In FIG. 12A, time information is managed for each memory block. On the other hand, referring to FIG. 12B, the time information mapping table MTP_tINF may be managed for each data defined by an address ADDR and a data length D_length. In FIG. 12B, the address ADDR may mean a first physical address indicating storage location of stored data in the memory blocks. That is, a plurality of entries included in the time information mapping table respectively include a start address ADDR, a data length D_length, and time information data tINF_DATA, which correspond to data. Each of the entries of the time information mapping table MTP_tINF represents time information of corresponding data. As shown in FIG. 12B, start addresses ADDR1 to ADDRn, data lengths LEN1 to LENn, and time information data t1 to tn, which respectively correspond to first to nth data, are stored in the time information mapping table.

It is noted that FIGS. 12A and 12B are simply illustrative, and that other various types of time information mapping tables may be configured without departing from the scope of the present invention.

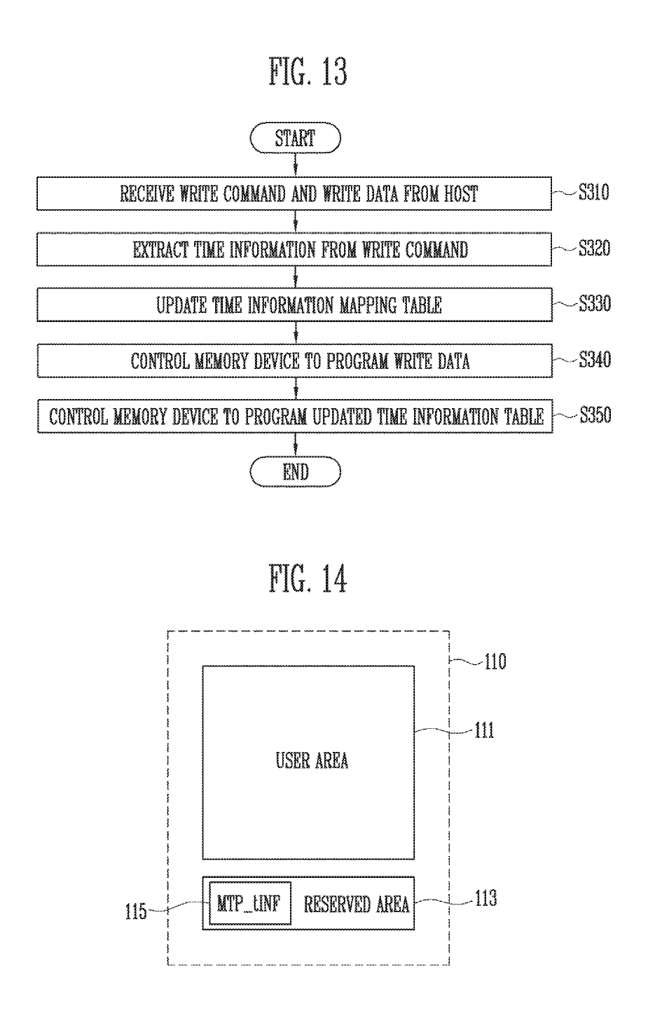

FIG. 13 is a flowchart illustrating an operating method of the memory controller in accordance with another embodiment of the present disclosure.

Referring to FIG. 13, first, the memory controller 1100 receives a write command WCMD and write data WDATA from the host 2000 in step S310. The step S310 may include the steps S110, S120, and S130 shown in FIG. 8A.

Subsequently, the processing unit 1120 of the memory controller 1100 extracts time information from the received write command WCMD in step S320. The time information extracted in the step S320 may be the time information 313 shown in FIG. 9A. In another embodiment, the time information extracted in the step S320 may be the time information 410 shown in FIG. 10B. In still another embodiment, the time information extracted in the step S320 may be the time information 343 shown in FIG. 11. In any case, the time information is generated by the host 2000, and may be information indicating a time at which the host 2000 generates the write command WCMD.

Subsequently, in step S330, the processing unit 1120 may update time information mapping table MTP_tINF, based on the extracted time information. As described above, the time information mapping table MTP_tINF may be stored in the time information buffer 1150 shown in FIG. 7. More specifically, when the memory system 1000 is turned on, the memory controller 1100 may read the time information mapping table MPT_tINF 200 stored in the memory device 100 and store the time information mapping table MPT_tINF 200 in the time information buffer 1150. The processing unit 1120 may update the time information mapping table MPT_tINF 200 stored in the time information buffer 1150. The time information mapping table shown in FIG. 12A or 12B may be updated.

When the time information mapping table MTP_tINF shown in FIG. 12A is stored in the time information buffer 1150, the processing unit 1150 may update the time information mapping table MTP_tINF in units of memory blocks. For example, when the write data WDATA received in the step S310 is stored in a free block, i.e., a memory block in which any data is not stored, the processing unit 1120 may generate a new entry of the time information mapping table MTP_tINF, and add, to the new entry, a block ID BLK id. of the memory block in which the write data WDATA is stored and time information data tINF_DATA extracted from a write command WCMD corresponding to the write data WDATA.

For example, when the write data WDATA received in the step S310 is stored in an open block, i.e., a memory block in which a valid data is stored, the processing unit 1120 may update the time information mapping table MTP_tINF according to characteristics of the time information data tINF_DATA. In an example, when a time at which a write command corresponding to data firstly programmed in a memory block is generated is stored as the time information data tINF_DATA as described above, the processing unit 1120 does not update the time information mapping table MTP_tINF. This is because the time information data tINF_DATA is not changed since the valid data has already been stored in the open block.

In another example, when a time at which a write command corresponding to data lastly programmed in a memory block is generated is stored as the time information data tINF_DATA as described above, the processing unit 1120 updates the time information mapping table MTP_tINF. This is because the corresponding time information data tINF_DATA is also changed since the lastly programmed data is changed when new data is stored in the state in which the valid data has already been stored in the open block.

When the time information mapping table MTP_tINF shown in FIG. 12B is stored in the time information buffer 1150, the processing unit 1120 may update the time information table MTP_tINF in units of data divided by the write command WCMD.

The processing unit 1120 may generate a new entry of the time information mapping table MTP_tINF, and add a physical address ADDR at which the write data WDATA starts being stored, a data length D_length of the write data WDATA, and time information data tINF_DATA extracted from the corresponding write command WCMD.

In step S340, the memory controller 1100 may control the memory device 100 to program the received write data WDATA. Also, in step S350, the memory controller 1100 may control the memory device 100 to program the time information mapping table MTP_tINF updated in the step S330.

The step S350 may be performed whenever the write command WCMD and the write data WDATA are received. Alternatively, step 350 may be performed shortly before the memory system 1000 is turned off. Before the memory system 1000 is turned off, the updated time information mapping table MTP_tINF is maintained in the time information buffer 1150. Therefore, the step S350 may be performed when the memory system 1000 is turned off.

According to the method shown in FIG. 13, when a write command WCMD and write data WDATA corresponding thereto are received, the memory controller 1100 updates time information mapping table MTP_tINF by extracting time information included in the write command WCMD. Thus, time information of data stored in the memory device 100 can be managed in the form of a table by the memory controller 1100. Accordingly, the memory controller 1100 can perform various operations, based on the time information mapping table.

FIG. 14 is a diagram illustrating a time information mapping table MTP_tINF stored in the memory cell array 110 of the memory device 100.

Referring to FIG. 14, the memory cell array 110 may be divided into a user area 111 and a reserved area 113. Each of the user area 111 and the reserved area 113 may include a plurality of memory blocks. Data received from the host 2000 may be stored in the user area 111. Except for data received from the host 2000, various data may be stored in the reserved area 113. For example, Content-Addressable Memory (CAM) data may be stored in the reserved area 113. The time information mapping table MTP_tINF 115 may be stored in the reserved area 113. When the memory system 1000 is turned on, the whole or a portion of the time information mapping table MTP_tINF 115 may be loaded by the memory controller 1100, to be stored in the time information buffer 1150.

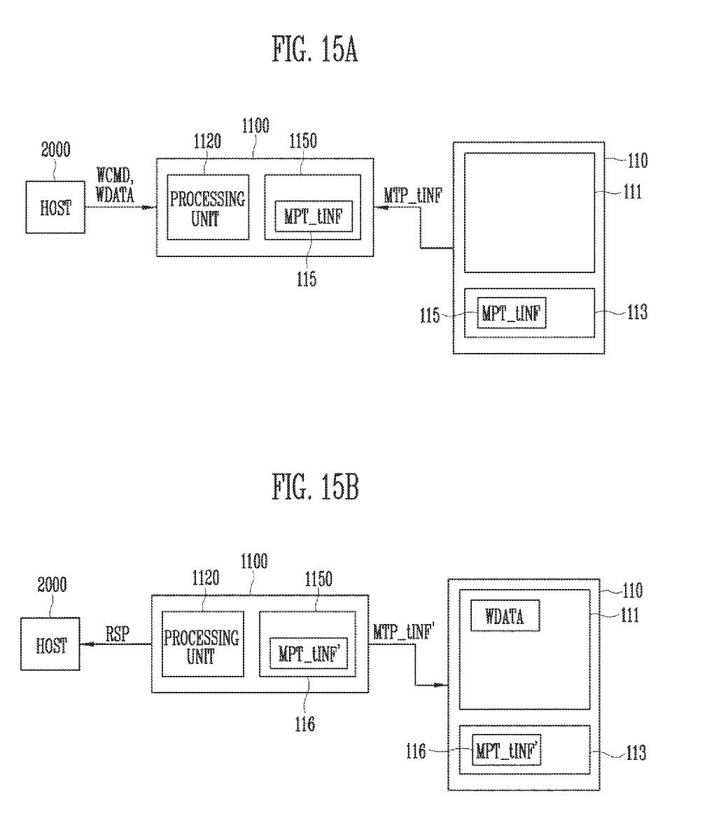

FIG. 15A is a block diagram illustrating a process of updating time information mapping table MTP_tINF when receiving a write command from the host 2000. In FIG. 15A, only the processing unit 1120 and the time information buffer 1150 of the memory controller 1100 are illustrated for convenience of description, and illustration of the other components is omitted. In addition, only the user area 111 and the reserved area 113 of the memory cell array 110 of the memory device 100 are illustrated, and illustration of the other components is omitted.

When the memory system 1000 is turned on, the memory controller 1100 may read the time information mapping table MTP_tINF 115 stored in the reserved area 113 and may store the read time information mapping table MTP_tINF 115 in the time information buffer 1150. When the time information mapping table MTP_tINF 115 is not stored in the reserved area 113, the processing unit 1120 of the memory controller 1100 may generate an empty time information mapping table MTP_tINF 115 and store the generated time information mapping table MTP_tINF 115 in the time information buffer 1150.

The host 2000 may transfer a write command WCMD and write data WDATA to the memory controller 1100 in step S310. The host 2000 may insert time information indicating a time at which the write command WCMD is generated into the write command WCMD or the write data WDATA, and transfer the write command WCMD or the write data WDATA to the memory controller 1100. The time information may be generated based on a time used in an operating system of the host 2000.

The processing unit 1120 may extract time information from the received write command WCMD or the received write data WDATA in step S320. Subsequently, the processing unit 1120 may update the time information mapping table MTP_tINF 115 in the buffer 1150, based on the extracted time information in step S330.

FIG. 15B is a block diagram illustrating a process of storing write data and an updated time information mapping table MTP_tINF in the memory device 110.

Referring to FIG. 15B, a time information mapping table MPT_tINF′ 116 updated by the processing unit 1120 is stored in the time information buffer 1150. The memory controller 1100 may control the memory device 100 to program received write data WDATA in the user area 111 of the memory cell array 110 in step S340. Also, the memory controller 1100 may control the memory device 100 to program the updated time information mapping table MPT_tINF′ 116 in the reserved area 113 of the memory cell array 110 in step S350.

FIG. 16 is a diagram illustrating the time information buffer 1150 for storing time information mapping table MTP_tINF and final time information.

As described above, the time information buffer 1150 may store a time information mapping table MPT_tINF 115. Meanwhile, in accordance with the embodiment shown in FIG. 16, the time information buffer 1150 may further store final time information LST_tINF 117.

The final time information LST_tINF 117 may mean time information inserted into the latest write command WCMD that the memory controller 1100 receives from the host 2000. Therefore, whenever the memory controller 1100 receives a write command WCMD from the host 2000, the final time information LST_tINF 117 may be updated based on time information included in the received write command WCMD.

Meanwhile, in this specification, it is described that time information is inserted into only a write command, to be transferred to the memory controller 1100. However, in some embodiments, time information may be inserted into another kind of command such as a read command, to be transferred to the memory controller 1100. The final time information LST_tINF 117 may indicate time information inserted into the latest command received from the host 2000, regardless of the kind of command. Therefore, whenever the memory controller 1100 receives a command from the host 2000, the final time information LST_tINF 117 may be updated based on time information included in the received command.

In general, the memory controller 1100 cannot autonomously detect a current time, and hence the current time may be replaced with the final time information LST_tINF 117. The final time information LST_tINF 117 may be used with the meaning of a time value closest to the current time.

In many embodiments, the final time information LST_tINF 117 may be used to approximately determine how much time elapses from a time indicated by each time information included in the time information mapping table MTP_tINF 115. Ideally, a time interval until a current time from the time at which the write command WCMD is generated may be calculated by comparing an accurate current time and the time information included in the time information mapping table MTP_tINF 115. However, as described above, the memory controller 1100 cannot autonomously detect a current time, and hence the current time is replaced with the final time information LST_tINF 117. A time interval from the time at which the write command WCMD is generated to the time at which the latest write command WCMD or another command is received may be calculated by comparing the final time information LST_tINF 117 and the time information included in the time information mapping table MTP_tINF 115.

For example, it is assumed that the time at which the lastly received write command WCMD is generated in the example of FIG. 12A is tBz, and corresponding data is stored in the zth memory block BLKz. The value of the final time information LST_tINF 117 may be stored as tBz.

As for each of the entries of FIG. 12A, a time interval from the time at which a write command is generated for each memory block to an approximately current time may be determined based on tBz that is the value of the final time information LST_tINF 117. The time interval from the time at which each write command is generated to the time indicated by the final time information LST_tINF 117 is defined as a program lapse time. The program lapse time is a value obtained by approximately calculating a time interval until a current time from the time at which the host 2000 generates a write command WCMD. In the example of FIG. 12A, the program lapse time of data stored in the first memory block BLK1 is determined as a time interval between the time tB1 and the time tBz. Meanwhile, the program lapse time of data stored in the second memory block BLK2 is determined as a time interval between the time tB2 and the time tBz.

In another example, it is assumed that the address at which write data WDATA corresponding to the lastly received write command WCMD is stored in the example of FIG. 12B is an nth address ADDRn. The value of the final time information LST_tINF 117 may be stored as tn.

As for each of the entries of FIG. 12B, a time interval from the time at which a write command is generated for each data to an approximately current time may be determined based on tn that is the value of the final time information LST_tINF 117. The time interval from the time at which each write command is generated to the time indicated by the final time information LST_tINF 117 is defined as a program lapse time. The program lapse time is a value obtained by approximately calculating a time interval until now from the time at which the host 2000 generates a write command WCMD. In the example of FIG. 12B, the program lapse time of data stored from a first address ADDR1 is determined as a time interval between a time t1 and the time tn. Meanwhile, the program lapse time of data stored from a second address ADDR2 is determined as a time interval between a time t2 and the time tn.

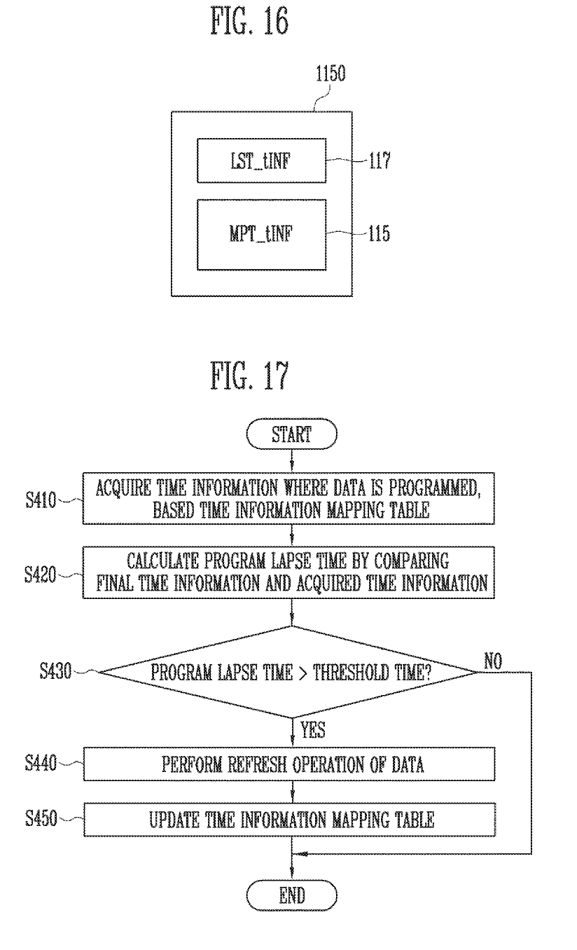

When the program lapse time increases, this may mean that it has been a long time from the time at which data corresponding to the program lapse time is programmed. When the program lapse time decreases, this may mean that it has been a short time from the time at which data corresponding to the program lapse time is programmed. Accordingly, the memory controller 1100 can efficiently perform various operations. For example, the memory controller 1100 may determine whether a refresh operation of data is to be performed based on the program lapse time. A method for determining whether a refresh operation of data is to be performed based on the program lapse time will be described later with reference to FIG. 17.

FIG. 17 is a flowchart illustrating an operating method of the memory controller in accordance with another embodiment of the present disclosure.

Referring to FIG. 17, first, in step S410, time information where data is programmed is acquired based on the time information mapping table MTP_tINF. In the step S410, the data as a target to acquire the time information may be referred to target data. Referring to FIG. 17 together with the embodiment of FIG. 12B, the target data is distinguished by an address, and time information data tINF_DATA of the target data may be acquired. For example, when data corresponding to a third address ADDR3 is target data, t3 may be acquired as time information where the target data is programmed.

In step S420, a program lapse time is calculated by comparing the final time information LST_tINF 117 and the time information acquired in the step S410. As described above, a time interval between the time indicated by the final time information LST_tINF 117 and the time indicated by the time information acquired in the step S410 may be calculated as the program lapse time.

In step S430, the program lapse time is compared with a predetermined threshold time.

When the program lapse time is smaller than or equal to the threshold time, this means that it has not been a long time from the time at which data is programmed, and therefore, the operation is ended without performing a refresh operation of data. On the other hand, when the program lapse time is larger than or equal to the threshold time, this means that it has been a long time from the time at which data is programmed. Therefore, a refresh operation of data may be required. Accordingly, a refresh operation of the target data is performed by proceeding to step S440. The refresh operation of data may mean an operation of re-programming data in which retention has occurred or data in which it is highly likely that retention will occur. Therefore, the physical address of data may be changed by the refresh operation.

In addition, the time at which the corresponding data is programmed is also changed by the refresh operation. Therefore, in step S450, the time information mapping table MTP_tINF is updated with respect to the refreshed data. In the case of the refresh operation, time information cannot be obtained from the host 2000, and hence the time information mapping table MTP_tINF may be updated in a manner that updates time information of the target data to a time indicated by the final time information LST_tINF 117.

For example, in the example of FIG. 12, when data corresponding to the third address ADDR3 is updated due to the refresh operation, the third address ADDR3 may be changed to the physical address of the refreshed data, and the time of corresponding time information data tINF_DATA may be changed from the time t3 to the time (e.g., tn) indicated by the final time information LST_tINF 117.

As described above, in the memory controller 1100 and the operating method thereof in accordance with the present disclosure, time information on the time at which a write command CMD is generated can be managed in the form of a table. Accordingly, the time at which individual data is programmed can be managed by the memory controller 1100, and be used in various manners. This provides wider flexibility to the operating method of the memory controller 1100. It can be seen that the time information mapping table MTP_tINF may be used in various fields in addition to the method shown in FIG. 17.

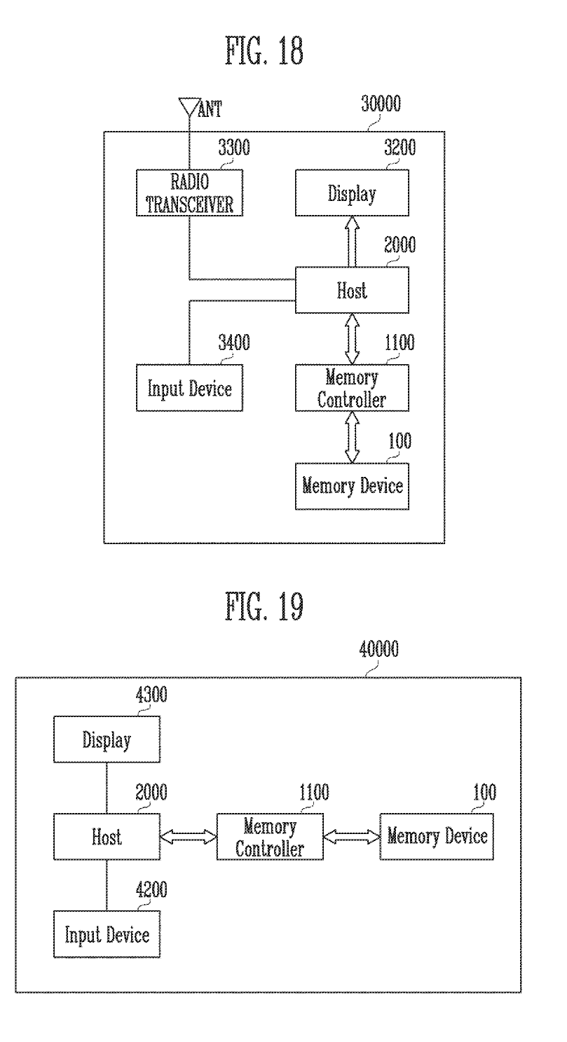

FIG. 18 is a diagram illustrating another embodiment of the memory system including the memory controller shown in FIG. 7.

Referring to FIG. 18, the system 30000 may be implemented as a cellular phone, a smart phone, a tablet PC, a personal digital assistant (PDA), or a wireless communication device.

The system 30000 may include a memory device 100 and a memory controller 1100 capable of controlling an operation of the memory device 100. The memory controller 1100 may control a data access operation of the memory device 100, e.g., a program operation, an erase operation, a read operation, or the like under the control of a host 2000. The memory controller 1100 and the memory device 100 of FIG. 18 may constitute the memory system 1000 shown in FIG. 1 or 7.

Data programmed in the memory device 100 may be output through a display 3200 under the control of the memory controller 11200.

A radio transceiver 3300 may transmit/receive radio signals through an antenna ANT. For example, the radio transceiver 3300 may convert a radio signal received through the antenna ANT into a signal that can be processed by the host 2000. Therefore, the host 2000 may process a signal output from the radio transceiver 3300 and transmit the processed signal to the memory controller 1100 or the display 3200. The memory controller 1100 may transmit the signal processed by the host 2000 to the semiconductor memory device 100. Also, the radio transceiver 3300 may convert a signal output from the host 2000 into a radio signal, and output the converted radio signal to an external device through the antenna ANT. An input device 3400 is a device capable of inputting a control signal for controlling an operation of the host 2000 or data to be processed by the host 2000, and may be implemented as a pointing device such as a touch pad or a computer mount, a keypad, or a keyboard. The host 2000 may control an operation of the display 3200 such that data output from the memory controller 1100, data output from the radio transceiver 3300, or data output from the input device 3400 can be output through the display 3200.

FIG. 19 is a diagram illustrating another embodiment of the memory system including the memory controller shown in FIG. 7.

Referring to FIG. 19, the system 40000 may be implemented as a personal computer (PC), a tablet PC, a net-book, an e-reader, a personal digital assistant (PDA), a portable multimedia player (PMP), an MP3 player, or an MP4 player.

The system 40000 may include a memory device 100 and a memory controller 1100 capable of controlling a data processing operation of the memory device 100. The memory controller 1100 and the memory device 100 of FIG. 19 may constitute the memory system 1000 shown in FIG. 1 or 7.

A host 2000 may output data stored in the memory device 100 through a display 4300 according to data input through an input device 4200. For example, the input device 4200 may be implemented as a pointing device such as a touch pad or a computer mouse, a keypad, or a keyboard.

The host 2000 may control the overall operations of the system 40000, and control an operation of the memory controller 1100.

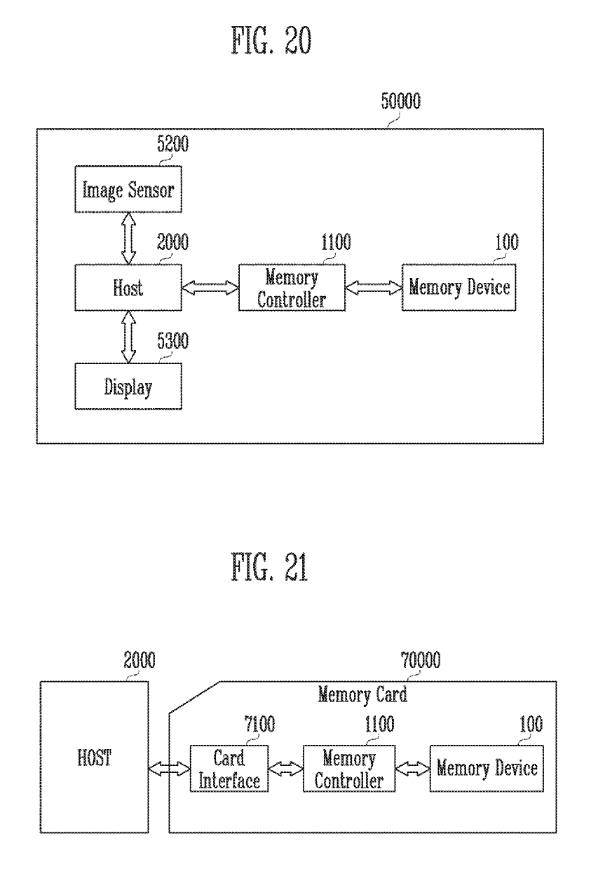

FIG. 20 is a diagram illustrating another embodiment of the memory system including the memory controller shown in FIG. 7.

Referring to FIG. 20, the system 50000 may be implemented as an image processing device, e.g., a digital camera, a mobile terminal having a digital camera attached thereto, a smart phone having a digital camera attached thereto, or a tablet PC having a digital camera attached thereto.

The system 50000 may include a memory device 100 and a memory controller 1100 capable of controlling a data processing operation of the memory device 100, e.g., a program operation, an erase operation, or a read operation. The memory controller 1100 and the memory device 100 of FIG. 20 may constitute the memory system 1000 shown in FIG. 1 or 7.

An image sensor 5200 of the system 50000 may convert an optical image into digital signals, and the converted digital signals may be transmitted to a host 2000 or the memory controller 1100. Under the control of the host 2000, the converted digital signals may be output through a display 5300, or be stored in the memory device 100 through the memory controller 1100. In addition, data stored in the memory device 100 may be output through the display 5300 under the control of the host 2000.

FIG. 21 is a diagram illustrating another embodiment of the memory system including the memory controller shown in FIG. 7.

Referring to FIG. 21, the system may include a host 2000 and a memory card 70000.

The memory card 70000 may be implemented with a smart card. The memory card 70000 may include a memory device 100, a memory controller 1100, and a card interface 7100. The memory controller 1100 and the memory device 100 of FIG. 21 may constitute the memory system 1000 shown in FIG. 1 or 7.

The memory controller 1100 may control data exchange between the memory device 100 and the card interface 7100. In some embodiments, the card interface 7100 may be a Secure Digital (SD) card interface or a Multi-Media Card (MMC) interface, but the present disclosure is not limited thereto. Also, the card interface 7100 may interface data exchange between a host 2000 and the memory controller 1100 according to a protocol of the host 2000. In some embodiments, the card interface 7100 may support a Universal Serial Bus (USB) protocol and an Inter-Chip (IC)-USB protocol. The card interface 7100 may mean hardware capable of supporting a protocol used by the host 2000, software embedded in the hardware, or a signal transmission scheme.

In accordance with the present disclosure, there can be provided a memory controller that can flexibly operate by adding time information to write data, and an operating method of the memory controller.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory controller for controlling an operation of a memory device, the memory controller comprising:
a time information buffer configured to store a time information mapping table; and
a processing unit configured to extract time information from a write command received from a host, and to update the time information mapping table based on the extracted time information.

2. The memory controller of claim 1,
wherein the time information mapping table is received from the memory device, and
wherein the time information is information indicating a time at which the host generates the write command.

3. The memory controller of claim 2, wherein a program operation of the memory device is controlled such that the updated time information is stored in the time information mapping table.

4. The memory controller of claim 2, wherein the time information mapping table includes:
block identification information identifying at least one block in which data is stored; and
at least one time information corresponding to the at least one block.

5. The memory controller of claim 4, wherein the time information is the time information extracted from the write command corresponding to firstly stored data among data stored in a corresponding block.

6. The memory controller of claim 4, wherein the time information is the time information extracted from the write command corresponding to lastly stored data among data stored in a corresponding block.

7. The memory controller of claim 2, wherein the time information mapping table includes:
address information indicating a physical address at which data is stored;
length information indicating a length of the data; and
time information extracted from a write command corresponding to the data.

8. The memory controller of claim 2, wherein the time information buffer further stores final time information that is the time information extracted from a lastly received write command.

9. The memory controller of claim 8, wherein the processing unit determines data on which a refresh operation is to be performed, based on the time information mapping table.

10. The memory controller of claim 9, wherein the processing unit determines that a refresh operation is to be performed on data of which program lapse time exceeds a predetermined threshold time by comparing the final time information and the time information of the time information mapping table.

11. A method for operating a memory controller, the method comprising:
receiving a write command and write data corresponding thereto from a host;
extracting time information from the write command; and
updating a time information mapping table, based on the extracted time information,
wherein the time information is information indicating a time at which the host generates the write command.

12. The method of claim 11, further comprising controlling the memory device to program the updated time information mapping table.

13. The method of claim 11, further comprising controlling the memory device to program the write data corresponding to the write command.

14. The method of claim 11, wherein the updating of the time information mapping table includes:
determining a physical address at which the write data is to be programmed; and
updating the time information mapping table based on time information corresponding to the write data and the determined physical address.

15. A method for operating a memory controller, the method comprising:
acquiring time information corresponding to a target data, based on a time information mapping table;
calculating a program lapse time of the target data by comparing final time information that is time information extracted from a write command lastly received from a host and the time information of the target data; and
performing a refresh operation of the target data, based on the program lapse time and a predetermined threshold time.

16. The method of claim 15, wherein the performing of the refresh operation includes:
comparing the program lapse time with the threshold time;
performing, when the program lapse time is larger than the threshold time, a refresh operation on the target data; and
updating the time information mapping table, based on the refresh operation.

17. The method of claim 16, wherein the updating of the time information mapping table includes updating time information corresponding to the refreshed target data as the final time information.
